(19) United States
(12) Patent Application Publication
(10) Pub. No.: US 2026/0237355 A1
(43) Pub. Date: Aug. 13, 2026

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Zhongman ZHAO, Beijing (CN); Yipeng CHEN, Beijing (CN); Ling SHI, Beijing (CN)

(21) Appl. No.: 19/152,430

(22) PCT Filed: Jul. 8, 2024
(86) PCT No.: PCT/CN2024/104169

§ 371 Date: Jul. 30, 2025

(30) Foreign Application Priority Data
Aug. 4, 2023 (CN) 202310981124.1

(51) Int. Cl. G09G 3/3266; G09G 3/00; G09G 3/20; G09G 3/3233

(52) U.S. Cl. CPC G09G 3/3266; G09G 3/035; G09G 3/2007; G09G 3/3233; G09G 2300/0408; G09G 2300/0426; G09G 2300/0819; G09G 2300/0842; G09G 2300/0861; G09G 2310/0283; G09G 2310/0286; G09G 2320/0233; G09G 2330/023

(57) ABSTRACT

The display substrate comprises a display region; the display region is provided with pixel driving circuits, a plurality of gate line groups and a plurality of gate connection line groups; a non-display region is provided with gate driving circuits; the gate driving circuits are electrically connected to the gate line groups; the non-display region comprises: a frame region and a binding region which are sequentially arranged in a direction away from the display region; the frame region comprises: a first linear frame region and a second linear frame region, the first linear frame region being located on the side of the display region away from the binding region, and the second linear frame region being located on the side of the display region close to the binding region.

### CROSS-REFERENCE TO RELATED APPLICATIONS

The present application is a U.S. National Phase Entry of International PCT Application No. PCT/CN 2024/104169 having an international filing date of Jul. 8, 2024, which claims priority to Chinese Patent Application No. 202310981124.1 filed on Aug. 4, 2023 and entitled “Display Substrate and Display Apparatus”. The above-identified applications are incorporated by reference herein in their entireties.

### TECHNICAL FIELD

The present disclosure relates to, but is not limited to, the field of display technologies, and more particularly, to a display substrate and a display apparatus.

### BACKGROUND

An organic light emitting diode (OLED) and a quantum dot light emitting diode (QLED) are active light emitting display devices and have advantages of self-illumination, a wide viewing angle, a high contrast ratio, low power consumption, an extremely high reaction speed, lightness and thinness, flexibility, and a low cost, etc. With constant development of display technologies, a flexible display apparatus (Flexible Display) in which an OLED or a QLED is used as a light emitting device and signal control is performed through a thin film transistor (TFT) has become a mainstream product in the field of display at present.

### SUMMARY

The following is a summary of subject matter described in detail in the present application. This summary is not intended to limit the protection scope of claims.

According to a first aspect, the present disclosure provides a display substrate including a display region and a non-display region. The display region is provided with pixel driving circuits arranged in an array, a plurality of gate line groups and a plurality of gate connection line groups. The non-display region is provided with a gate driving circuit. A pixel driving circuit includes a plurality of transistors. A gate line group is electrically connected to a gate electrode of at least one transistor and the gate driving circuit, respectively. The gate line group includes at least one gate line, and any gate line in the gate line group extends at least partially in a first direction.

A boundary of the display region includes a plurality of arc-shaped boundaries and a plurality of straight-line boundaries, and any straight-line boundary is respectively connected to two arc-shaped boundaries. The non-display region includes a frame region and a binding region which are sequentially provided in a direction away from the display region. The binding region is located on a side of the frame region, and the frame region located outside a straight-line boundary is referred to as a straight-line frame region. The frame region includes a first straight-line frame region and a second straight-line frame region arranged in a second direction. The first straight-line frame region is located on a side of the display region away from the binding region, and the second straight-line frame region is located on a side of the display region close to the binding region. The first direction intersects the second direction.

A portion of the gate driving circuit is located in at least one of the first straight-line frame region and the second straight-line frame region, a gate connection line group is electrically connected to a local frame circuit and a gate line group connected to the local frame circuit, respectively, and the local frame circuit includes a gate driving circuit located in at least one of the first straight-line frame region and the second straight-line frame region.

In an exemplary embodiment, the gate driving circuit includes a first driving circuit to an M-th driving circuit, an m-th driving circuit includes a plurality of cascaded m-th type shift registers, the gate driving circuit is divided into a plurality of shift register units corresponding one-to-one to the plurality of gate line groups, and the shift register units are electrically connected to the corresponding gate line groups, where 1≤m≤M.

Any shift register unit includes a first type shift register to an M-th type shift register, and the gate line group includes a first gate line to an M-th gate line.

In an exemplary embodiment, the first straight-line frame region and the second straight-line frame region are each divided into a first area and a second area which are respectively located on two sides of a first midline, and the first midline is a midline of the display region extending in the second direction.

The frame region further includes a third straight-line frame region and a fourth straight-line frame region arranged in the first direction, and the third straight-line frame region and the fourth straight-line frame region are symmetrically provided relative to the first midline.

The gate driving circuit includes a first gate driving group including an (N1+1)-th shift register unit to an N2-th shift register unit. The first gate driving group is located in at least one of the third straight-line frame region and the fourth straight-line frame region, where N1<N, N2<N, and N2>N1, N being a quantity of shift register units included in the gate driving circuit.

All shift register units in the first gate driving group are arranged in the second direction, and a first type shift register to an M-th type shift register located in any shift register unit in the first gate driving group are arranged in the first direction.

In an exemplary embodiment, the gate driving circuit further includes a second gate driving group including a first shift register unit to an N1-th shift register unit, and a third gate driving group including an (N2+1)-th shift register unit to an N-th shift register unit.

The second gate driving group is located in the first area of the first straight-line frame region, and the third gate driving group is located in the first area of the second straight-line frame region.

Alternatively, the second gate driving group is located in the second area of the first straight-line frame region, and the third gate driving group is located in the second area of the second straight-line frame region.

Alternatively, the second gate driving group is located in the first area and the second area of the first straight-line frame region, and the third gate driving group is located in the first area and the second area of the second straight-line frame region.

In an exemplary embodiment, the second gate driving group is located in the first area and the second area of the first straight-line frame region, and the second gate driving group located in the first area of the first straight-line frame region and the second gate driving group located in the second area of the first straight-line frame region are symmetrically provided with respect to the first midline.

The third gate driving group is located in the first area and the second area of the second straight-line frame region, and the third gate driving group located in the first area of the second straight-line frame region and the third gate driving group located in the second area of the second straight-line frame region are symmetrically provided relative to the first midline.

In an exemplary embodiment, all shift register units located in the second gate driving group are arranged in the first direction, all shift register units located in the third gate driving group are arranged in the first direction, and a first type shift register to an M-th type shift register located in any one of the shift register units located in the second gate driving group and the third gate driving group are arranged in the second direction.

In an exemplary embodiment, all m-th type shift registers in the second gate driving group and the third gate driving group are referred to as an m-th type shift register group.

In the first straight-line frame region and the second straight-line frame region, all shift registers located in a shift register group of a same type are arranged in the first direction, and a first type shift register group to an M-th type shift register group are arranged in the first direction.

In an exemplary embodiment, the rounded corner frame region includes a first rounded corner frame region to a fourth rounded corner frame region. The first rounded corner frame region is located between the first straight-line frame region and the third straight-line frame region, the second rounded corner frame region is located between the first straight-line frame region and the fourth straight-line frame region, the third rounded corner frame region is located between the second straight-line frame region and the third straight-line frame region, and the fourth rounded corner frame region is located between the second straight-line frame region and the fourth straight-line frame region.

The gate driving circuit further includes a second gate driving group including a first shift register unit to an N1-th shift register unit, and a third gate driving group including an (N2+1)-th shift register unit to an N-th shift register unit.

The second gate driving group is located in the first area of the first straight-line frame region and the first rounded corner frame region, and the third gate driving group is located in the first area of the second straight-line frame region and the third rounded corner frame region.

Alternatively, the second gate driving group is located in the second area of the first straight-line frame region and the second rounded corner frame region, and the third gate driving group is located in the second area of the second straight-line frame region and the fourth rounded corner frame region.

Alternatively, the second gate driving group is located in the first area and the second area of the first straight-line frame region, the first rounded corner frame region and the second rounded corner frame region, and the third gate driving group is located in the first area and the second area of the second straight-line frame region, the third rounded corner frame region and the fourth rounded corner frame region.

In an exemplary embodiment, all m-th type shift registers in the second gate driving group and the third gate driving group are referred to as an m-th type shift register group.

An i-th type shift register group in the second gate driving group is located in the first area of the first straight-line frame region, a j-th type shift register group in the second gate driving group is located in the first rounded corner frame region, an i-th type shift register group in the third gate driving group is located in the first area of the second straight-line frame region, a j-th type shift register group in the third gate driving group is located in the third rounded corner frame region, where i is at least one number from 1 to M, and j is a remaining number from 1 to M except i.

Alternatively, an i-th type shift register group in the second gate driving group is located in the second area of the first straight-line frame region, a j-th type shift register group in the second gate driving group is located in the second rounded corner frame region, an i-th type shift register group in the third gate driving group is located in the second area of the second straight-line frame region, and a j-th type shift register group in the third gate driving group is located in the fourth rounded corner frame region.

Alternatively, an i-th type shift register group in the second gate driving group is located in the first area and the second area of the first straight-line frame region, a j-th type shift register group in the second gate driving group is located in the first rounded corner frame region and the second rounded corner frame region, an i-th type shift register group in the third gate driving group is located in the first area and the second area of the second straight-line frame region, and a j-th type shift register group in the third gate driving group is located in the third rounded corner frame region and the fourth rounded corner frame region.

In an exemplary embodiment, all shift registers in any type of shift register group located in any one of the first straight-line frame region and the second straight-line frame region are arranged in the first direction.

A quantity of types of shift register groups located in any one of the first straight-line frame region and the second straight-line frame region is at least two, and at least two types of shift register groups located in any one of the first straight-line frame region and the second straight-line frame region are arranged in the second direction.

In an exemplary embodiment, all shift registers in any type of shift register group located in any one of the first straight-line frame region and the second straight-line frame region are arranged in the first direction.

A quantity of types of shift register groups located in any one of the first straight-line frame region and the second straight-line frame region is at least two, and at least two types of shift register groups located in any one of the first straight-line frame region and the second straight-line frame region are arranged in the first direction.

In an exemplary embodiment, all shift registers in any type of shift register group located in at least one of the first rounded corner frame region, the second rounded corner frame region, the third rounded corner frame region, and the fourth rounded corner frame region are arranged along an arc-shaped boundary.

A quantity of types of shift register groups located in the at least one of the first rounded corner frame region, the second rounded corner frame region, the third rounded corner frame region, and the fourth rounded corner frame region is at least two, and at least two types of shift register groups located in the at least one of the first rounded corner frame region, the second rounded corner frame region, the third rounded corner frame region, and the fourth rounded corner frame region are sequentially arranged in a direction away from the display region.

In an exemplary embodiment, a portion of the gate driving circuit is located in the first straight-line frame region and the second straight-line frame region, the gate driving circuit located in the first straight-line frame region and the gate driving circuit located in the second straight-line frame region are symmetrically provided along a second midline, and the second midline is a midline of the display region extending in the first direction.

In an exemplary embodiment, the gate connection line group includes a first gate signal connection line to an M-th gate signal connection line, and an m-th gate signal connection line is electrically connected to an m-th type shift register and an m-th gate line, respectively.

Any one of the first gate signal connection line to the M-th gate signal connection line includes a first connection line, a second connection line and a third connection line. The first connection line and the third connection line extend in the second direction, and the second connection line extends in the first direction.

For the m-th gate signal connection line, the first connection line is electrically connected to the m-th type shift register connected to the m-th gate signal connection line and the second connection line, respectively, and the third connection line is electrically connected to the second connection line and the m-th gate line connected to the m-th gate signal connection line.

In an exemplary embodiment, the gate connection line group includes a first gate signal connection line to an M-th gate signal connection line, and an m-th gate signal connection line is electrically connected to an m-th type shift register and an m-th gate line, respectively.

The m-th gate signal connection line extends in the second direction.

In an exemplary embodiment, the first connection line is provided in a different layer from any gate line in the gate line group, the second connection line and the third connection line are provided in a same layer and are provided in a different layer from any gate line in the gate line group.

The first connection line is provided in a different layer from the second connection line.

In an exemplary embodiment, for the m-th gate signal connection line, the first connection line is electrically connected to the second connection line through a first via, and the third connection line is electrically connected to an m-th gate line connected to the m-th gate signal connection line through a second via. The first via is located in the display region, and the second via is located outside the display region, and is spaced from a boundary of the display region by a distance less than a distance between a boundary of the gate driving circuit close to the display region and the display region.

In an exemplary embodiment, the display region is further provided with a plurality of first traces and a plurality of second traces.

The plurality of first traces extend in the first direction and are arranged in the first direction with second connection lines, and the first traces and the second connection lines are provided at intervals.

The plurality of second traces extend in the second direction and are arranged in the second direction with first connection lines, and the second traces and the first connection lines are provided at intervals.

The first traces are provided on a same layer as the second connection lines, and the second traces are provided on a same layer as the first connection lines.

In a second aspect, the present disclosure further provides a display apparatus, including the display substrate described above.

Other aspects of the present disclosure may be comprehended after the drawings and the detailed descriptions are read and understood.

### BRIEF DESCRIPTION OF DRAWINGS

Accompanying drawings are intended to provide an understanding of technical solutions of the present application and form a part of the specification, and are used to explain the technical solutions of the present application together with embodiments of the present application, and do not constitute a limitation on the technical solutions of the present application.

FIG. 1 is a schematic diagram of a structure of a display substrate.

FIG. 2 is a schematic diagram of division of a frame region of a display substrate.

FIG. 3 is a schematic diagram of a structure of another display substrate.

FIG. 4 is a schematic diagram of a structure of a display substrate provided by an embodiment of the present disclosure.

FIG. 5 is a first equivalent circuit diagram of a pixel driving circuit.

FIG. 6 is a second equivalent circuit diagram of a pixel driving circuit.

FIG. 7 is a third equivalent circuit diagram of a pixel driving circuit.

FIG. 8 is a first schematic diagram of a structure of a display substrate provided by an exemplary embodiment.

FIG. 9 is a second schematic diagram of a structure of a display substrate provided by an exemplary embodiment.

FIG. 10 is a third schematic diagram of a structure of a display substrate provided by an exemplary embodiment.

FIG. 11 is a fourth schematic diagram of a structure of a display substrate provided by an exemplary embodiment.

FIG. 12 is a fifth schematic diagram of a structure of a display substrate provided by an exemplary embodiment.

FIG. 13 is a sixth schematic diagram of a structure of a display substrate provided by an exemplary embodiment.

FIG. 14 is a seventh schematic diagram of a structure of a display substrate provided by an exemplary embodiment.

FIG. 15 is an eighth schematic diagram of a structure of a display substrate provided by an exemplary embodiment.

FIG. 16 is a schematic diagram of connection of a gate connection line group.

FIG. 17 is a first schematic diagram of signal lines in a display region.

FIG. 18 is a second schematic diagram of signal lines in a display region.

### DETAILED DESCRIPTION

To make objectives, technical solutions, and advantages of the present disclosure clearer, the embodiments of the present disclosure will be described in detail below with reference to the accompanying drawings. It is to be noted that embodiments may be implemented in multiple different forms. Those of ordinary skills in the art may easily understand such a fact that implementations and contents may be transformed into various forms without departing from the purpose and scope of the present disclosure. Therefore, the present disclosure should not be explained as being limited to the contents recorded in the following embodiments only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one implementation of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, an “electrical connection” includes a case that constituent elements are connected together through an element with a certain electrical action. The “element with a certain electrical action” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, other elements with various functions, etc.

In the specification, “disposed in a same layer” adopted refers to a structure formed by patterning two (or more than two) structures through a same patterning process, and their materials may be the same or different. For example, materials of precursors for forming multiple structures disposed in a same layer are the same, and materials finally formed may be the same or different.

With the development of OLED display technology, the demand for narrow frames is getting higher and higher. A boundary of a display region includes arc-shaped boundaries, and a non-display region includes rounded corner regions located outside the arc-shaped boundaries. Arc arrangement of a circuit structure in the rounded corner regions takes up a large space, which makes it impossible for a display product to achieve a narrow frame.

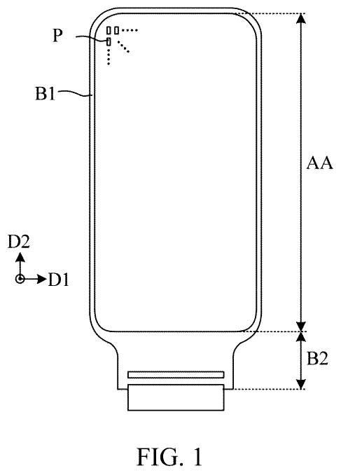

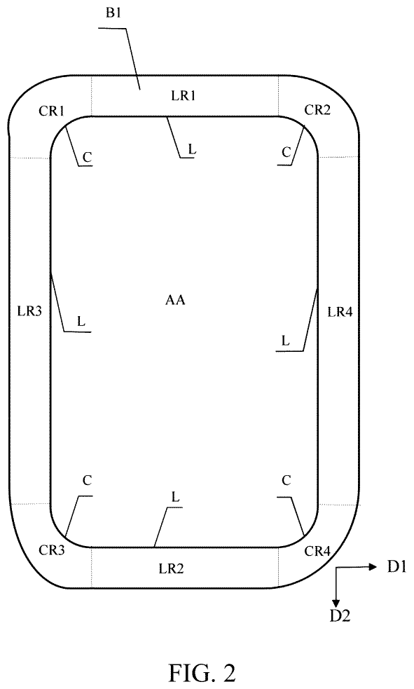

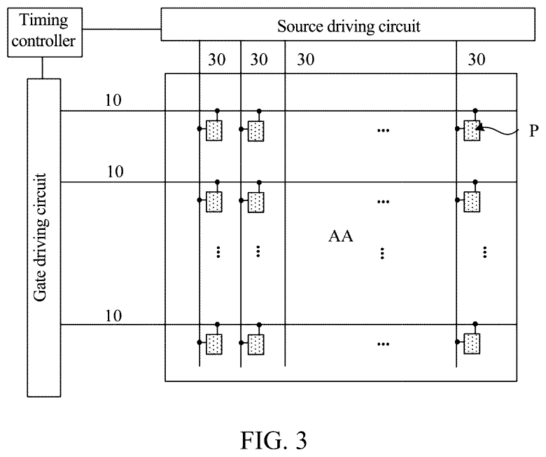

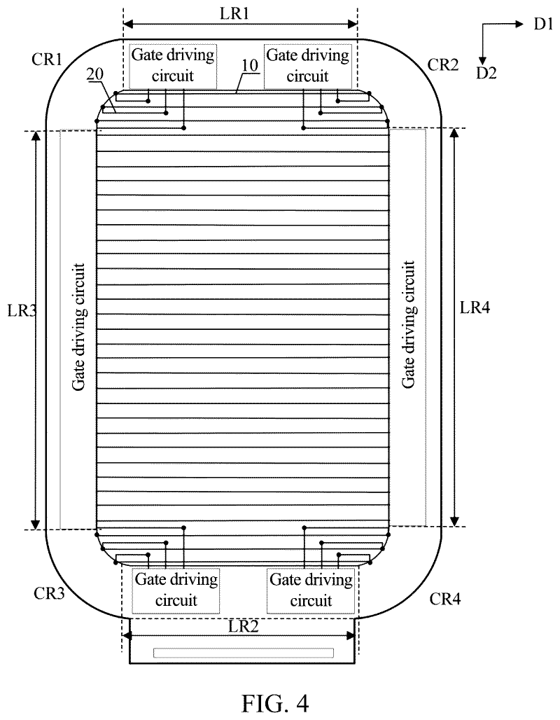

FIG. 1 is a schematic diagram of a structure of a display substrate. FIG. 2 is a schematic diagram of division of a frame region of a display substrate. FIG. 3 is a schematic diagram of a structure of another display substrate. FIG. 4 is a schematic diagram of a structure of a display substrate provided by an embodiment of the present disclosure. As shown in FIGS. 1 to 4, an embodiment of the present disclosure provides a display substrate including a display region AA and a non-display region. The display region AA is provided with pixel driving circuits P arranged in an array, a plurality of gate line groups 10, and a plurality of gate connection line groups 20. The non-display region is provided with a gate driving circuit. A pixel driving circuit includes a plurality of transistors, and a gate line group 10 is electrically connected to a gate electrode of at least one transistor and the gate driving circuit, respectively. The gate line group 10 includes at least one gate line, and any gate line in the gate line group 10 extends at least partially in a first direction D1.

In an exemplary embodiment, as shown in FIGS. 2 and 4, a boundary of the display region AA includes a plurality of arc-shaped boundaries C and a plurality of straight-line boundaries L, and any straight-line boundary L is respectively connected to two arc-shaped boundaries C. The non-display region includes a frame region B1 and a binding region B2 which are sequentially provided in a direction away from the display region AA, the binding region B2 is located on a side of the frame region B1, and the frame region located outside a straight-line boundary is referred to as a straight-line frame region. The frame region includes a first straight-line frame region LR1 and a second straight-line frame region LR2 arranged in a second direction D2. The first straight-line frame region LR1 is located on a side of the display region AA away from the binding region B2, the second straight-line frame region LR2 is located on a side of the display region AA close to the binding region B2, and the first direction D1 intersects the second direction D2.

In an exemplary embodiment, as shown in FIG. 4, a portion of the gate driving circuit is located in at least one of the first straight-line frame region LR1 and the second straight-line frame region LR2, and a gate connection line group 20 is electrically connected to a local frame circuit and a gate line group connected to the local frame circuit, respectively. The local frame circuit includes a gate driving circuit located in at least one of the first straight-line frame region and the second straight-line frame region.

In an exemplary embodiment, a shape of the boundary of the display region AA may be a rounded rectangle, which is not limited here in the present disclosure. The display substrate provided by the present disclosure may achieve a function of bending four sides at a large angle, thus improving a wrinkling problem of module attaching and improving a yield of products.

In an exemplary embodiment, the frame region located outside the arc-shaped boundary is referred to as a rounded corner frame region.

In the present disclosure, since a portion of the gate driving circuit is located in at least one of the first straight-line frame region LR1 and the second straight-line frame region LR2, an area occupied by a circuit structure located in the rounded corner frame region may be reduced. In addition, since the gate connection line group 20 electrically connected to the local frame circuit and the gate line group 10 connected to the local frame circuit is located in the display region AA, a quantity of signal lines located in the non-display region may also be reduced, so that narrow frame of the display substrate may be realized.

In an exemplary embodiment, the display region AA includes pixel units arranged in an array, at least one pixel unit includes at least three sub-pixels, and at least one sub-pixel includes a pixel driving circuit and a light emitting device. A pixel driving circuit located in a same sub-pixel is electrically connected to a light emitting device and is configured to drive the light emitting device to emit light.

In an exemplary embodiment, the pixel unit may include a red (R) sub-pixel, a green (G) sub-pixel, and a blue (B) sub-pixel, or may include a red sub-pixel, a green sub-pixel, a blue sub-pixel, and a white sub-pixel, which is not limited in the present disclosure.

In an exemplary embodiment, the light emitting device may be an Organic Light Emitting Diode (OLED) or a Quantum dot Light Emitting Diode (QLED). Among them, the OLED may include a first electrode (anode), an organic light-emitting layer, and a second electrode (cathode) that are stacked.

In an exemplary embodiment, as shown in FIG. 1, the frame region B1 is located on a periphery of the display region, and the binding region is located on a side of the frame region B2 away from the display region AA.

In an exemplary embodiment, the binding region B2 may include a lead region, a bending region, and a composite circuit region which are provided sequentially in a direction away from the display region AA, the lead region is connected to the display region AA, the bending region is connected to the lead region, and the composite circuit region is connected to the bending region.

In an exemplary embodiment, as shown in FIGS. 2 and 3, the display region is further provided with a data signal line 30, and the non-display region may be further provided with a timing controller and a source driving circuit.

In an exemplary embodiment, the timing controller may provide a control signal and a gray scale value suitable for the specification of the source driving circuit to the data driving circuit, and may provide a start signal, a clock signal suitable for the gate driving circuit and the like to the gate driving circuit.

In an exemplary embodiment, the source driving circuit may generate a data voltage to be provided to a plurality of data signal lines 30 using the gray scale value and the control signal received from the timing controller. For example, the source driving circuit may sample a gray-scale value using a clock signal, and apply a data voltage corresponding to the gray-scale value to the data signal line 30 by taking a pixel row as a unit.

In an exemplary embodiment, the gate driving circuit may generate a scan signal to be provided to the gate line by receiving a clock signal, a start signal, and the like from the timing controller. For example, the gate driving circuit may sequentially provide a signal with an on-level pulse to the gate line group. For example, the gate driving circuit may be configured in a form of a shift register, and may generate a scan signal in a manner of sequentially transmitting a start signal to a next-stage circuit under control of a clock signal.

In an exemplary embodiment, the display region is further provided with a data connection line. An embodiment of the present disclosure provides a display substrate, and a structure in which a data connection line is located in a display region (Fanout in AA, abbreviated as FIAA) is adopted. Ends of a plurality of data connection lines are correspondingly connected to a plurality of data signal lines in the display region, the other ends of the plurality of data connection lines extend to a binding region and are correspondingly connected to an integrated circuit in the binding region. Since the binding region does not need to be provided with fan-shaped oblique lines, a width of a fan-out region is reduced, and a width of a lower frame is effectively reduced.

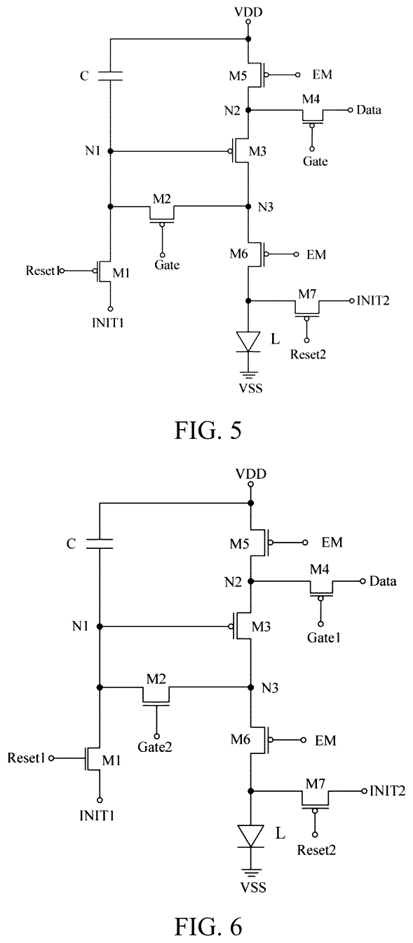

In an exemplary embodiment, FIG. 5 is a first equivalent circuit diagram of a pixel driving circuit. As shown in FIG. 5, the pixel driving circuit may include seven transistors (a first transistor M1 to a seventh transistor M7), a capacitor C, and nine signal lines (a data signal line Data, a scan signal line Scan, a first reset signal line Reset1, a second reset signal line Reset2, a light emitting signal line EM, a first initial signal line INIT1, a second initial signal line INIT2, a high-level power line VDD and a low-level power line VSS).

In an exemplary embodiment, FIG. 6 is a second equivalent circuit diagram of a pixel driving circuit. As shown in FIG. 6, the pixel driving circuit may include 7 transistors (a first transistor M1 to a seventh transistor M7), a capacitor C, and ten signal lines (a data signal line Data, a first scan signal line Scan1, a second scan signal line Scan2, a first reset signal line Reset1, a second reset signal line Reset2, a light emitting signal line EM, a first initial signal line INIT1, a second initial signal line INIT2, a high-level power supply line VDD, and a low-level power supply line VSS).

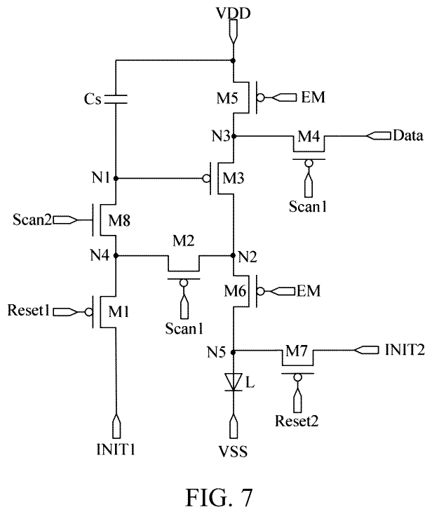

In an exemplary embodiment, FIG. 7 is a third equivalent circuit diagram of a pixel driving circuit. As shown in FIG. 7, the pixel driving circuit may include eight transistors (a first transistor M1 to an eighth transistor M8), a capacitor C, and ten signal lines (a data signal line Data, a first scan signal line Scan1, a second scan signal line Scan2, a first reset signal line Reset1, a second reset signal line Reset2, a light emitting signal line EM, a first initial signal line INIT1, a second initial signal line INIT2, a high-level power supply line VDD, and a low-level power supply line VSS).

In an exemplary embodiment, for the pixel driving circuit provided in FIG. 5, a signal of the second reset signal line Reset2 may be the same as a signal of the first reset signal line Reset1, or may be the same as a signal of the scan signal line Scan. For the pixel driving circuit provided in FIGS. 6 and 7, a signal of the second reset signal line Reset2 may be the same as a signal of the first reset signal line Reset1, or may be the same as a signal of the first scan signal line Scan1.

Transistors may be classified as N-type transistors and P-type transistors according to characteristics of the transistors. When a transistor is a P-type transistor, its turn-on voltage is a low-level voltage (e.g., 0V, −5V, −10V, or another suitable voltage), and its turn-off voltage is a high-level voltage (e.g., 5V, 10V, or another suitable voltage). When a transistor is an N-type transistor, its turn-on voltage is a high-level voltage (e.g., 5V, 10V, or another suitable voltage), and its turn-off voltage is a low-level voltage (e.g., OV, −5V, −10V, or another suitable voltage).

In an exemplary embodiment, all the transistors in the pixel driving circuit may be low temperature poly silicon thin film transistors, or may be oxide thin film transistors, or may be low temperature poly silicon thin film transistors and oxide thin film transistors. An active layer of a low temperature poly silicon thin film transistor is made of Low Temperature Poly Silicon (LTPS for short), and an active layer of an oxide thin film transistor is made of an oxide semiconductor (Oxide). The low temperature poly silicon thin film transistors have advantages such as high migration rate and fast charging, and the oxide thin film transistors have advantages such as low leakage current. The low temperature poly silicon thin film transistors and the oxide thin film transistors are integrated on one display substrate to form a Low Temperature Poly-Silicon+Oxide (LTPO) display substrate, so that the advantages of both the low temperature poly silicon thin film transistors and the oxide thin film transistors may be utilized, thereby realizing low-frequency driving, decreasing power consumption, and improving display quality.

In an exemplary embodiment, as shown in FIG. 5, the first transistor MI to the seventh transistor M7 are P-type transistors. The pixel driving circuit provided in FIG. 5 is suitable for an LTPS display substrate.

In an exemplary embodiment, as shown in FIG. 6, the first transistor M1 and the second transistor M2 are N-type transistors, and the third transistor M3 to the seventh transistor M7 are P-type transistors. The pixel driving circuit provided in FIG. 6 is suitable for an LTPO display substrate.

In an exemplary embodiment, as shown in FIG. 7, the first transistor MI to the seventh transistor M7 are P-type transistors, and the eighth transistor M8 is an N-type transistor. The pixel driving circuit provided in FIG. 7 is suitable for an LTPO display substrate.

In an exemplary embodiment, a quantity of driving circuits included in the gate driving circuit may be two, three, or more, depending on a structure of the display substrate, which is not defined in the present disclosure.

In an exemplary embodiment, for the display substrate including the pixel driving circuit provided in FIG. 5, the gate driving circuit may include a reset driving circuit, a scan driving circuit, and a light emitting driving circuit, or a scan driving circuit and a light emitting driving circuit. The gate line group includes a first reset signal line, a second reset signal line, a scan signal line, and a light emitting signal line. When the gate driving circuit includes a reset driving circuit, a scan driving circuit and a light emitting driving circuit, the reset driving circuit is electrically connected to the first reset signal line and the second reset signal line, the scan driving circuit is electrically connected to the scan signal line, and the light emitting driving circuit is electrically connected to the light emitting signal line. When the gate driving circuit includes a scan driving circuit and a light emitting driving circuit, the reset driving circuit is electrically connected to the first reset signal line, the second reset signal line, and the scan signal line, the scan driving circuit is electrically connected to the scan signal line, and the light emitting driving circuit is electrically connected to the light emitting signal line.

In an exemplary embodiment, for the display substrate including the pixel driving circuit provided in FIGS. 6 and 7, the gate driving circuit may include a reset driving circuit, a first scan driving circuit, a second scan driving circuit, and a light emitting driving circuit, or may include a first scan driving circuit, a second scan driving circuit, and a light emitting driving circuit, and the gate line group includes a first reset signal line, a second reset signal line, a first scan signal line, a second scan signal and a light emitting signal line. When the gate driving circuit includes a reset driving circuit, a first scan driving circuit, a second scan driving circuit and a light emitting driving circuit, the reset signal line is electrically connected to the first reset signal line and the second reset signal line, the first scan driving circuit is electrically connected to the first scan signal line, the second scan driving circuit is electrically connected to the second scan signal line, and the light emitting driving circuit is electrically connected to the light emitting signal line. When the gate driving circuit includes a first scan driving circuit, a second scan driving circuit and a light emitting driving circuit, the first scan driving circuit is electrically connected to the first reset signal line, the second reset signal line is electrically connected to the first scan signal line, the second scan driving circuit is electrically connected to the second scan signal line, and the light emitting driving circuit is electrically connected to the light emitting signal line.

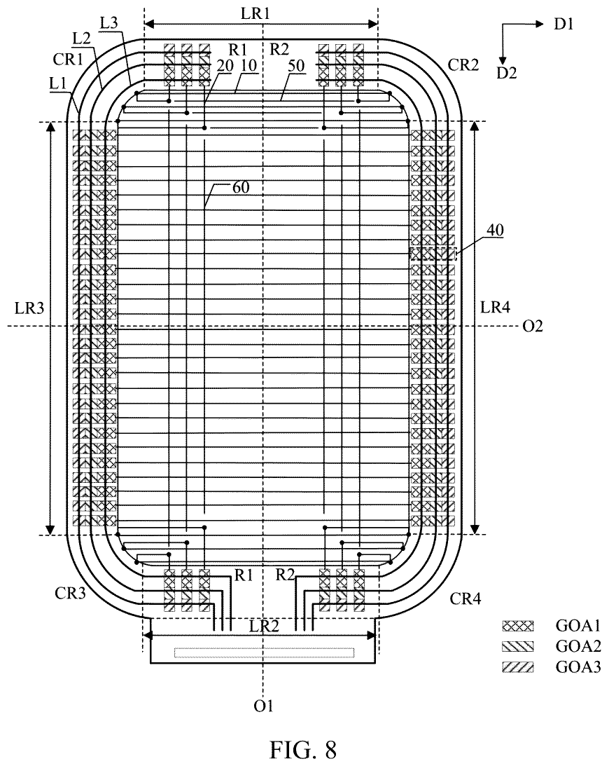

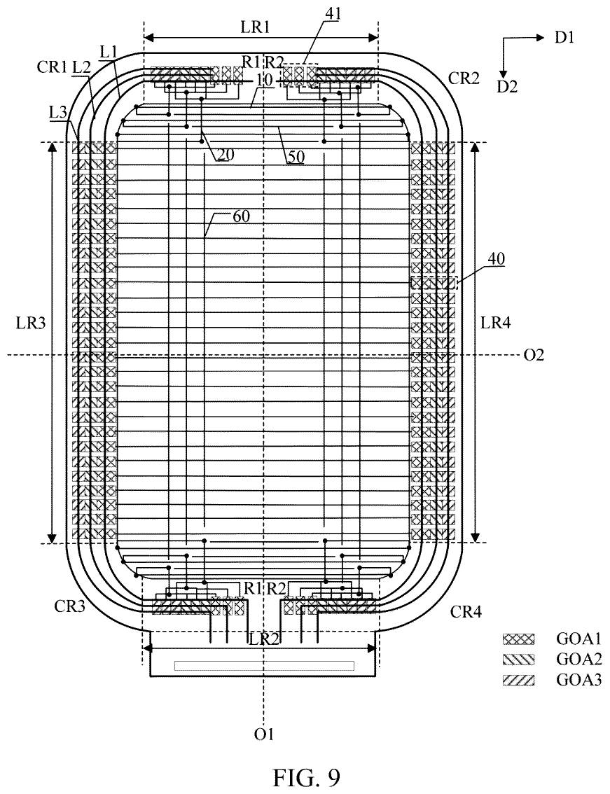

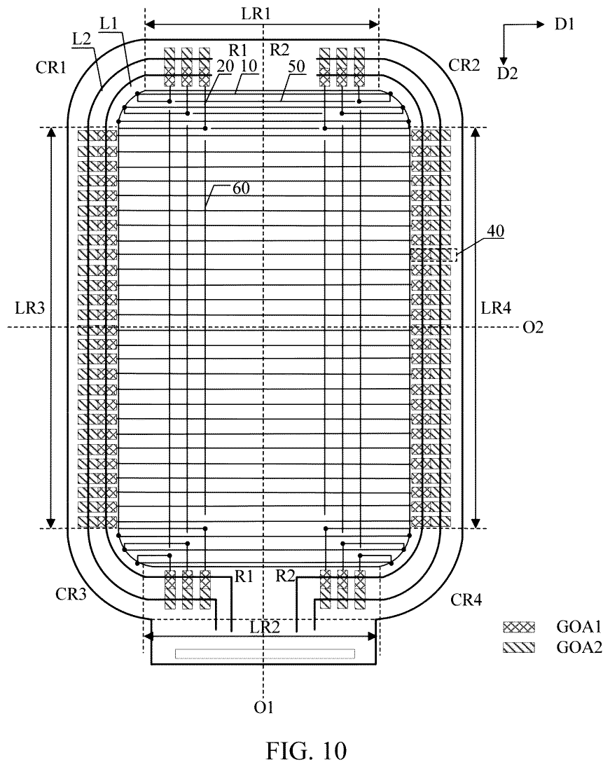

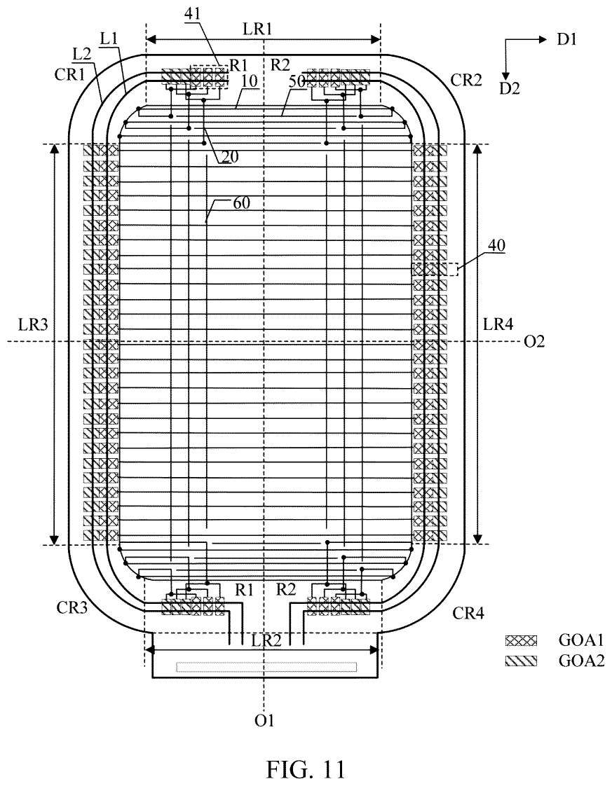

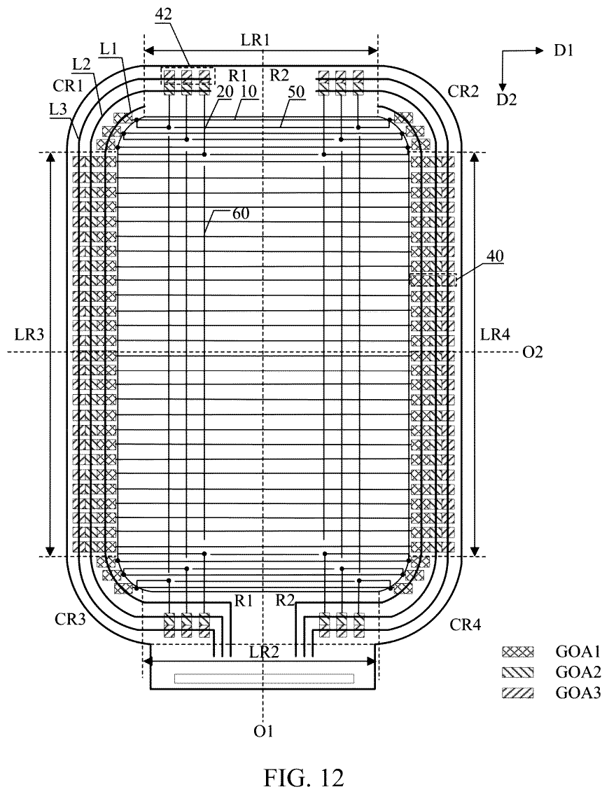

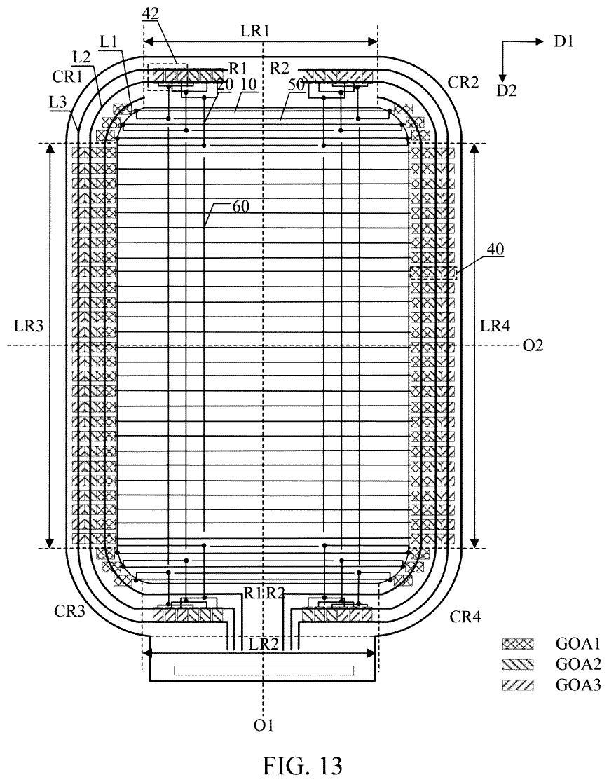

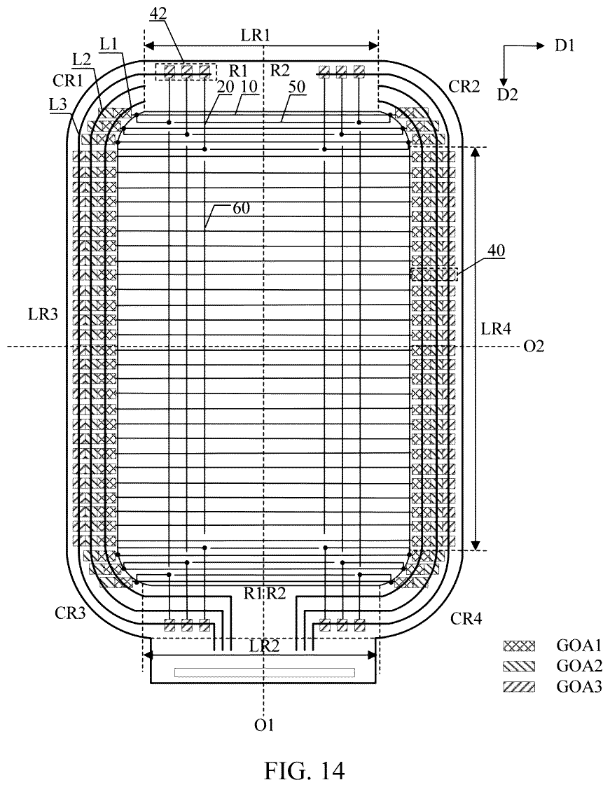

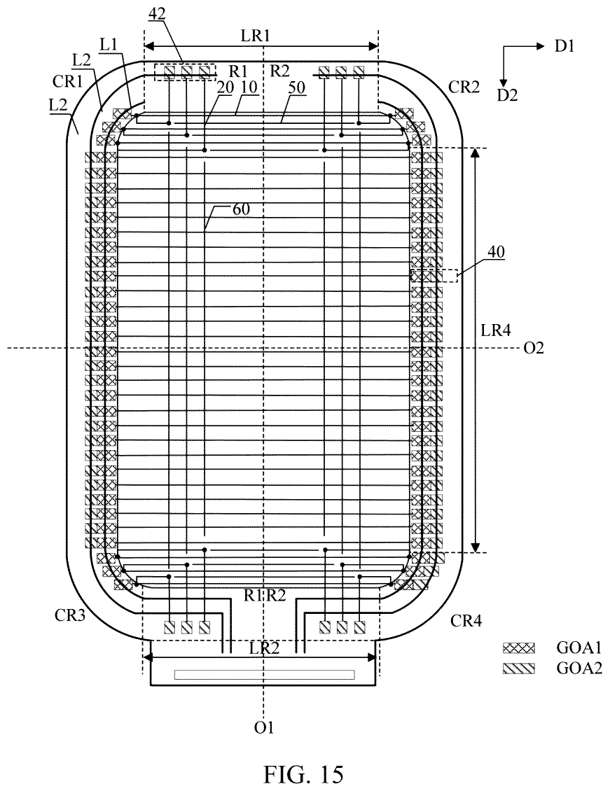

In an exemplary embodiment, FIG. 8 is a first schematic diagram of a structure of a display substrate provided by an exemplary embodiment. FIG. 9 is a second schematic diagram of a structure of a display substrate provided by an exemplary embodiment. FIG. 10 is a third schematic diagram of a structure of a display substrate provided by an exemplary embodiment. FIG. 11 is a fourth schematic diagram of a structure of a display substrate provided by an exemplary embodiment. FIG. 12 is a fifth schematic diagram of a structure of a display substrate provided by an exemplary embodiment. FIG. 13 is a sixth schematic diagram of a structure of a display substrate provided by an exemplary embodiment. FIG. 14 is a seventh schematic diagram of a structure of a display substrate provided by an exemplary embodiment. FIG. 15 is an eighth schematic diagram of a structure of a display substrate provided by an exemplary embodiment. As shown in FIGS. 8 to 15, the gate driving circuit may include a first driving circuit to an M-th driving circuit, an m-th driving circuit includes a plurality of cascaded m-th type shift registers, the gate driving circuit is divided into a plurality of shift register units 40 corresponding one-to-one to the plurality of gate line groups 10, and the shift register units 40 are electrically connected to the corresponding gate line groups 10, where 1≤m≤M. FIGS. 8, 9, and 12 to 14 are illustrated with M=3 as an example, and FIGS. 10, 11, and 15 are illustrated with M=2 as an example.

In an exemplary embodiment, a circuit structure of any one of the first type shift register to the M-th type shift register may be 8T2C, 10T3C, 12T3C, 13T3C, or 16T3C, which is not defined in the present disclosure.

In an exemplary embodiment, as shown in FIGS. 8 to 15, any shift register unit 40 includes a first type shift register to an M-th type shift register. For example, when M=3, the display substrate may be an LTPO display substrate, and the shift register unit may include a first type shift register GOA1 to a third type shift register GOA3; and when M=2, the display substrate may be an LTPS display substrate, and the shift register unit may include a first type shift register GOA1 and a second type shift register GOA2.

In an exemplary embodiment, M is a positive integer greater than or equal to 2, that is, the gate driving circuit includes at least two driving circuits.

In an exemplary embodiment, a quantity of shift registers of any type in any shift register unit may be at least one. In an exemplary embodiment, FIGS. 8 to 15 are illustrated with an example in which a quantity of any shift registers in any shift register unit is one.

In an exemplary embodiment, a quantity of shift registers included in the light emitting driving circuit in any shift register unit may be at least two, and a quantity of shift registers included in the reset driving circuit in any shift register unit may be at least two.

In an exemplary embodiment, the gate line group 10 may include a first gate line to an M-th gate line, and the M-th type shift register is electrically connected to at least one m-th gate line. For example, when M=3, gate lines may include a first gate line to a third gate line, the first gate line may be a first scan signal line in FIGS. 6 and 7, the second gate line may be a second scan signal line in FIGS. 6 and 7, and the third gate line may be a light emitting signal line in FIGS. 6 and 7. The first type shift register GOAL is electrically connected to at least one first gate line, the second type shift register GOA2 is electrically connected to at least one second gate line, and the third type shift register GOA3 is electrically connected to at least one third gate line. For example, when M=2, gate lines may include a first gate line and a second gate line, the first gate line may be a scan signal line in FIG. 5, and the second gate line may be a light emitting signal line in FIG. 5. The first type shift register GOAL is electrically connected to at least one scan signal line, and the second type shift register GOA2 is electrically connected to at least one light emitting signal line.

In an exemplary embodiment, for example, when M=3, a quantity of the first gate lines and a quantity of the third gate lines connected to a same shift register unit may both be one, or two or more, which is not defined in the present disclosure. For example, when M=2, a quantity of the first gate lines and a quantity of the second gate lines connected to a same shift register unit may both be one, or two or more, which is not defined in the present disclosure.

In an exemplary embodiment, a quantity of i-th gate lines and a quantity of j-th gate lines connected to a same shift register unit are the same, where 1≤i, j≤M, and i is not equal to j, that is, any type of shift register in a same shift register unit controls sub-pixels of a same row.

In an exemplary embodiment, a quantity of stages of any type of shift register included in each shift register unit is related to a quantity of gate lines connected to each type of shift register and a quantity of gate lines connected to any shift register unit. For example, taking an example in which a quantity of the first gate lines and a quantity of the third gate lines connected to a same shift register unit are both two, the first type shift register and one first gate line, the second type shift register and two second gate lines, and the third type shift register and two third gate lines, any shift register unit may include two stages of the first type shift register, one stage of the second type shift register and one stage of the third type shift register.

In an exemplary embodiment, quantities of the m-th gate lines connected to different shift register units are the same. For example, when M=3, quantities of the first gate lines connected to different shift register units are the same, quantities of the second gate lines connected to different shift register units are the same, and quantities of the third gate lines connected to different shift register units are the same.

In an exemplary embodiment, as shown in FIGS. 2, 4, and 8 to 14, the rounded corner frame region may include a first rounded corner frame region CR1 to a fourth rounded corner frame region CR4. The first rounded corner frame region CR1 is located between the first straight-line frame region LR1 and the third straight-line frame region LR3, the second rounded corner frame region CR2 is located between the first straight-line frame region LR1 and the fourth straight-line frame region LR4, the third rounded corner frame region CR3 is located between the second straight-line frame region LR2 and the third straight-line frame region LR3, and the fourth rounded corner frame region CR4 is located between the second straight-line frame region LR2 and the fourth straight-line frame region LR4.

In an exemplary embodiment, as shown in FIGS. 8 to 15, the first straight-line frame region LR1 and the second straight-line frame region LR2 are each divided into a first area R1 and a second area R2 which are respectively located on two sides of a first midline O1, and the first midline O1 is a midline of the display region AA extending in the second direction D2.

In an exemplary embodiment, as shown in FIGS. 8 to 15, the frame region may further include a third straight-line frame region LR3 and a fourth straight-line frame region LR4 arranged in the first direction D1, and the third straight-line frame region LR3 and the fourth straight-line frame region LR4 are symmetrically provided with respect to the first midline O1.

In an exemplary embodiment, as shown in FIGS. 8 to 15, the gate driving circuit includes a first gate driving group including an (N1+1)-th shift register unit to an N2-th shift register unit.

In an exemplary embodiment, as shown in FIGS. 8 to 15, the first gate driving group is located in at least one of the third straight-line frame region LR3 and the fourth straight-line frame region LR4, where N1<N, N2<N, and N2>N1, N being a quantity of shift register units included in the gate driving circuit. FIGS. 8 to 15 are illustrated with an example in which the first gate driving group is located in the third straight-line frame region LR3 and the fourth straight-line frame region LR4. FIGS. 8 to 15 are illustrated with N1=3 and N−N2=3 as an example.

In an exemplary embodiment, as shown in FIGS. 8 to 15, all shift register units 40 in the first gate driving group are arranged in the second direction D2, and a first type shift register to an M-th type shift register located in any one of the shift register units 40 in the first gate driving group are arranged in the first direction D1. The present disclosure does not limit an arrangement order of the first type shift register to the M-th type shift register.

For example, when M=3, the first type shift register may be located on a side of the second type shift register close to the display region, and the third type shift register may be located on a side of the second type shift register away from the display region. Alternatively, the first type shift register may be located on a side of the second type shift register away from the display region, or the third type shift register may be located on a side of the second type shift register close to the display region. Alternatively, the first type shift register may be located on a side of the third type shift register close to the display region, and the second type shift register may be located on a side of the third type shift register away from the display region. Alternatively, the first type shift register may be located on a side of the third type shift register away from the display region, and the second type shift register may be located on a side of the third type shift register close to the display region. Alternatively, the second type shift register may be located on a side of the first type shift register close to the display region, and the third type shift register may be located on a side of the first type shift register away from the display region. Alternatively, the second type shift register may be located on a side of the first type shift register away from the display region, and the third type shift register may be located on a side of the first type shift register close to the display region. FIGS. 8, 9, and 12 to 14 are illustrated with an example in which the first type shift register may be located on a side of the second type shift register close to the display region, and the third type shift register may be located on a side of the second type shift register away from the display region.

For example, when M=2, the first type shift register may be located on a side of the second type shift register close to the display region, or may be located on a side of the second type shift register away from the display region. FIGS. 10, 11, and 15 are illustrated with an example in which the first type shift register may be located on a side of the second type shift register close to the display region.

In an exemplary embodiment, as shown in FIGS. 8 to 15, the first gate driving group is located in the third straight-line frame region LR3 and the fourth straight-line frame region LR4, and the first gate driving group located in the third straight-line frame region and the first gate driving group located in the fourth straight-line frame region are symmetrically provided with respect to the first midline O1. By symmetrically providing the first gate driving group located in the third straight-line frame region and the first gate driving group located in the fourth straight-line frame region with respect to the first midline O1, display uniformity of the display substrate may be ensured.

In an exemplary embodiment, as shown in FIGS. 5 to 15, the gate driving circuit further includes a second gate driving group including a first shift register unit to an N1-th shift register unit, and a third gate driving group including an (N2+1)-th shift register unit to an N-th shift register unit. For example, as shown in FIGS. 8 to 15, the second gate driving group may include a first shift register unit to a third shift register unit, and the third gate driving group may include a last shift register unit to a third-to-last shift register unit.

In an exemplary embodiment, the second gate driving group may be located in the first straight-line frame region LR1, and the third gate driving group may be located in the second straight-line frame region LR2. Alternatively, the second gate driving group may be located in the first straight-line frame region LR1 and a partial rounded corner region, and the third gate driving group may be located in the second straight-line frame region LR2 and a partial rounded corner frame region.

In an exemplary embodiment, the second gate driving group may be located in the first straight-line frame region, and the third gate driving group may be located in the second straight-line frame region. Thus, all shift register units are located in the straight-line frame region, and the rounded corner frame region is not occupied, thereby avoiding the need to provide a circuit structure in the rounded corner frame region, and realizing a narrow frame of the display substrate.

In an exemplary embodiment, the second gate driving group may be located in the first straight-line frame region and a partial rounded corner region, and the third gate driving group may be located in the second straight-line frame region and a partial rounded corner frame region, so that a quantity of circuit structures located in the rounded corner frame region may be reduced, thereby realizing a narrow frame of the display substrate.

In an exemplary embodiment, the second gate driving group may be located in the first straight-line frame region, the third gate driving group may be located in the second straight-line frame region, the second gate driving group may be located in the first area R1 of the first straight-line frame region LR1, and the third gate driving group may be located in the first area R1 of the second straight-line frame region LR2. Alternatively, the second gate driving group may be located in the second area R2 of the first straight-line frame region LR1, and the third gate driving group may be located in the second area R2 of the second straight-line frame region LR2. Alternatively, the second gate driving group is located in the first area R1 and the second area R2 of the first straight-line frame region LR1, and the third gate driving group is located in the first area R1 and the second area R2 of the second straight-line frame region LR2. FIGS. 8 to 11 are illustrated with an example in which the second gate driving group is located in the first area R1 and the second area R2 of the first straight-line frame region LR1, and the third gate driving group is located in the first area R1 and the second area R2 of the second straight-line frame region LR2.

In an exemplary embodiment, as shown in FIGS. 8 to 11, an entire gate driving circuit is provided only in the straight-line frame region, and is not provided in the rounded corner frame region, thereby avoiding the need to provide a circuit structure in the rounded corner frame region, and realizing a narrow frame of the display substrate.

In an exemplary embodiment, as shown in FIGS. 8 to 11, the second gate driving group is located in the first area R1 and the second area R2 of the first straight-line frame region LR1, and the second gate driving group located in the first area R1 of the first straight-line frame region LR1 and the second gate driving group located in the second area R2 of the first straight-line frame region LR2 are symmetrically provided with respect to the first midline O1.

In an exemplary embodiment, as shown in FIGS. 8 to 11, the third gate driving group is located in the first area R1 and the second area R2 of the second straight-line frame region LR2, and the third gate driving group located in the first area R1 of the second straight-line frame region LR2 and the third gate driving group located in the second area R2 of the second straight-line frame region LR2 are symmetrically provided with respect to the first midline O1.

In an exemplary embodiment, as shown in FIGS. 8 and 10, all shift register units 40 located in the second gate driving group are arranged in the first direction D1, all shift register units 40 located in the third gate driving group are arranged in the first direction D1, and a first type shift register to an M-th type shift register located in any one of the shift register units in the second gate driving group and the third gate driving group are arranged in the second direction D2. A first type shift register to a third type shift register in any one of the shift register units located in the first straight-line frame region LR1 and the second straight-line frame region LR2 in FIG. 8 are arranged in the second direction D2, and a first type shift register and a second type shift register in any one of the shift register units located in the first straight-line frame region LR1 and the second straight-line frame region LR2 in FIG. 10 are arranged in the second direction D2.

In an exemplary embodiment, as shown in FIGS. 9 and 11, all m-th type shift registers in the second gate driving group and the third gate driving group are referred to as an m-th type shift register group 41, and in the first straight-line frame region LR1 and the second straight-line frame region LR2, all shift registers located in a shift register group of a same type are arranged in the first direction D1, and a first type shift register group to an M-th type shift register group are arranged in the first direction D1. That is, all types of shift registers located in the first straight-line frame region LR1 and the second straight-line frame region LR2 are arranged in the first direction D1. By arranging all the shift registers located in the first straight-line frame region LR1 and the second straight-line frame region LR2 in the first direction D1, widths of the first straight-line frame region LR1 and the second straight-line frame region LR2 may be reduced, and an area of the first straight-line frame region and the second straight-line frame region may be reduced, thereby further realizing a narrow frame.

In an exemplary embodiment, as shown in FIGS. 12 to 15, the second gate driving group is located in the first straight-line frame region and a partial rounded corner region, the third gate driving group is located in the second straight-line frame region and a partial rounded corner frame region, the second gate driving group may be located in the first area R1 of the first straight-line frame region LR1 and the first rounded corner frame region CR1, and the third gate driving group may be located in the first area R1 of the second straight-line frame region LR2 and the third rounded corner frame region CR3. Alternatively, the second gate driving group may be located in the second area R2 of the first straight-line frame region LR1 and the second rounded corner frame region CR2, and the third gate driving group may be located in the second area R2 of the second straight-line frame region LR2 and the fourth rounded corner frame region CR4. Alternatively, the second gate driving group may be located in the first area R1 and the second area R2 of the first straight-line frame region LR1, the first rounded corner frame region CR1 and the second rounded corner frame region CR2, and the third gate driving group may be located in the first area R1 and the second area R2 of the second straight-line frame region LR2, the third rounded corner frame region CR3 and the fourth rounded corner frame region CR4. FIGS. 12 to 15 are illustrated with an example in which the second gate driving group is located in the first area R1 and the second area R2 of the first straight-line frame region LR1, the first rounded corner frame region CR1 and the second rounded corner frame region CR2, and the third gate driving group is located in the first area R1 and the second area R2 of the second straight-line frame region LR2, the third rounded corner frame region CR3 and the fourth rounded corner frame region CR4.

In an exemplary embodiment, as shown in FIGS. 12 to 15, all m-th type shift registers in the second gate driving group and the third gate driving group are referred to as an m-th type shift register group 42. For example, when M =3, the second gate driving group and the third gate driving group may include a first type shift register group to a third type shift register group; and when M=2, the second gate driving group and the third gate driving group include a first type shift register group and a second type shift register group.

In an exemplary embodiment, an i-th type shift register group in the second gate driving group may be located in the first area R1 of the first straight-line frame region LR1, a j-th type shift register group in the second gate driving group may be located in the first rounded corner frame region CR1, an i-th type shift register group in the third gate driving group may be located in the first area R1 of the second straight-line frame region LR2, and a j-th type shift register group in the third gate driving group may be located in the third rounded corner frame region CR3, where i is at least one number from 1 to M, and j is a remaining number from 1 to M except i. For example, when M=2, i may be 1, j may be 2, or i may be 2, j may be 1; and when M=3, i may be 1, j may be 2 and 3, or i may be 2, j may be 1 and 3, or i may be 3, j may be 1 and 2, or i may be 1 and 2, j may be 3, or i may be 2 and 3, j may be 1, or i may be 1 and 3, j may be 2.

In an exemplary embodiment, an i-th type shift register group in the second gate driving group is located in the second area R2 of the first straight-line frame region LR1, a j-th type shift register group in the second gate driving group is located in the second rounded corner frame region CR2, an i-th type shift register group in the third gate driving group is located in the second area R2 of the second straight-line frame region LR2, and a j-th type shift register group in the third gate driving group is located in the fourth rounded corner frame region CR4.

In an exemplary embodiment, an i-th type shift register group in the second gate driving group is located in the first area R1 and the second area R2 of the first straight-line frame region LR1, a j-th shift register group in the second gate driving group is located in the first rounded corner frame region CR1 and the second rounded corner frame region CR2, an i-th type shift register group in the third gate driving group is located in the first area R1 and the second area R2 of the second straight-line frame region LR2, and a j-th type shift register group in the third gate driving group is located in the third rounded corner frame region CR3 and the fourth rounded corner frame region CR4. For example, FIGS. 12 and 13 are illustrated with an example in which the second type shift register group and the third type shift register group in the second gate driving group are located in the first area R1 and the second area R2 of the first straight-line frame region LR1, the first type shift register group in the second gate driving group is located in the first rounded corner frame region CR1 and the second rounded corner frame region CR2, the second type shift register group and the third type shift register group in the third gate driving group are located in the first area R1 and the second area R2 of the second straight-line frame region LR2, and the first type shift register group in the third gate driving group are located in the third rounded corner frame region CR3 and the fourth rounded corner frame region CR4. FIG. 14 is illustrated with an example in which the third type shift register group in the second gate driving group is located in the first area R1 and the second area R2 of the first straight-line frame region LR1, the first type shift register group and the second type shift register group in the second gate driving group are located in the first rounded corner frame region CR1 and the second rounded corner frame region CR2, the third type shift register group in the third gate driving group is located in the first area R1 and the second area R2 of the second straight-line frame region LR2, and the first type shift register group and the second type shift register group in the third gate driving group are located in the third rounded corner frame region CR3 and the fourth rounded corner frame region CR4. FIG. 15 is illustrated with an example in which the second type shift register group in the second gate driving group is located in the first area R1 and the second area R2 of the first straight-line frame region LR1, the first type shift register group in the second gate driving group is located in the first rounded corner frame region CR1 and the second rounded corner frame region CR2, the second type shift register group in the third gate driving group is located in the first area R1 and the second area R2 of the second straight-line frame region LR2, and the first type shift register group in the third gate driving group is located in the third rounded corner frame region CR3 and the fourth rounded corner frame region CR4.

In an exemplary embodiment, a straight-line frame circuit group includes groups of shift registers of at least one type located in the first straight-line frame region or the second straight-line frame region, and a rounded corner frame circuit group includes groups of shift registers of at least one type located in the rounded corner region. A position of a driving circuit in which the straight-line frame circuit group is located in the third straight-line frame region or the fourth straight-line frame region is provided on a side of a position of a driving circuit in which a right angle frame circuit group is located in third straight-line frame region or the fourth straight-line frame region away from the display region, that is, a shift register group included in the driving circuit in the third straight-line frame region or the fourth straight-line frame region away from the display region is provided in the first straight-line frame region or the second straight-line frame region, and a shift register group included in the driving circuit in the third straight-line frame region or the fourth straight-line frame region close to the display region is provided in the rounded-corner frame region. For example, in a case of M=2, when a first driving circuit is located on a side of a second driving circuit close to the display region, a shift register group located in the first straight-line frame region or the second straight-line frame region is a second type shift register group, and a shift register group located in the rounded corner frame region may be a first type shift register group. When the first driving circuit is located on a side of the second driving circuit away from the display region, a shift register group located in the first straight-line frame region or the second straight-line frame region may be a second type shift register group, and a shift register group located in the rounded corner frame region may be a first type shift register group.

In an exemplary embodiment, a quantity of types of shift register groups located in the first straight-line frame region LR1 and the second straight-line frame region LR2 is at least one. FIGS. 12 and 13 are illustrated with an example in which a quantity of types of shift register groups located in the first straight-line frame region LR1 and the second straight-line frame region LR2 is two. FIGS. 14 and 15 are illustrated with an example in which a quantity of types of shift register groups located in the first straight-line frame region LR1 and the second straight-line frame region LR2 is one.

In an exemplary embodiment, as shown in FIGS. 12 to 15, all shift registers in any type of shift register group 42 located in any one of the first straight-line frame region LR1 and the second straight-line frame region LR2 are arranged in the first direction D1.

In an exemplary embodiment, as shown in FIG. 12, a quantity of types of shift register groups located in any one of the first straight-line frame region LR1 and the second straight-line frame region LR2 is at least two, and at least two types of shift register groups located in any one of the first straight-line frame region LR1 and the second straight-line frame region LR2 are arranged in the second direction D2.

In an exemplary embodiment, as shown in FIG. 13, a quantity of types of shift register groups located in any one of the first straight-line frame region LR1 and the second straight-line frame region LR2 is at least two, and at least two types of shift register groups 42 located in any one of the first straight-line frame region LR1 and the second straight-line frame region LR2 are arranged in the first direction D1.

In an exemplary embodiment, as shown in FIGS. 12 to 15, all shift registers in any type of shift register group located in at least one of the first rounded corner frame region CR1, the second rounded corner frame region CR2, the third rounded corner frame region CR3, and the fourth rounded corner frame region CR4 are arranged along an arc-shaped boundary.

In an exemplary embodiment, as shown in FIGS. 12 to 15, a quantity of types of shift register groups in at least one of the first rounded corner frame region CR1, the second rounded corner frame region CR2, the third rounded corner frame region CR3, and the fourth rounded corner frame region CR4 is at least two, and at least two types of shift register groups located in at least one of the first rounded corner frame region CR1, the second rounded corner frame region CR2, the third rounded corner frame region CR3, and the fourth rounded corner frame region CR4 are sequentially arranged in a direction away from the display region AA.

In an exemplary embodiment, as shown in FIGS. 8 to 15, a gate driving circuit located in the first straight-line frame region LR1 and a gate driving circuit located in the second straight-line frame region LR2 are symmetrically provided along a second midline O2, and the second midline O2 is a midline of the display region AA extending in the first direction D1. By symmetrically providing the gate driving circuit located in the first straight-line frame region LR1 and the gate driving circuit located in the second straight-line frame region LR2 along the second midline 02, uniformity of display of the display substrate may be ensured.

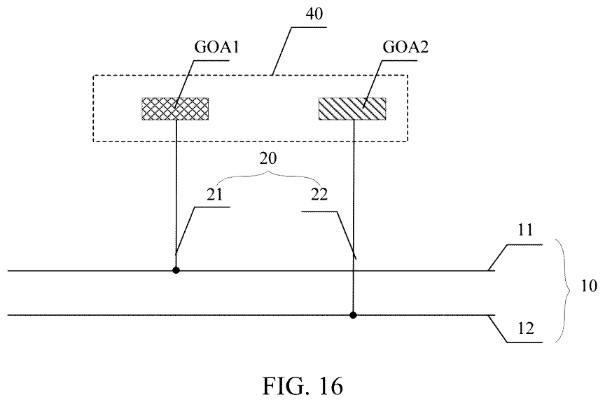

In an exemplary embodiment, FIG. 16 is a schematic diagram of connection of a gate connection line group. As shown in FIG. 16, a gate connection line group 20 includes a first gate signal connection line to an M-th gate signal connection line, and an m-th gate signal connection line is electrically connected to an m-th type shift register and an m-th gate line, respectively. FIG. 16 is illustrated with M=2 as an example. As shown in FIG. 16, the gate connection line group 20 includes a first gate signal connection line 21 and a second gate signal connection line 22. In this case, a gate line 10 includes a first gate line 11 and a second gate line 12, the first gate signal connection line 21 is electrically connected to the first type shift register GOA1 located in the shift register unit 40 and the first gate line 11, respectively, and the second gate signal connection line 22 is electrically connected to the second type shift register GOA2 and the second gate line 12, respectively. For example, in a case of M=3, the gate connection line group includes a first gate signal connection line to a third gate signal connection line. The first gate signal connection line is electrically connected to the first type shift register and the first gate line, respectively, the second gate signal connection line is electrically connected to the second type shift register and the second gate line, respectively, and the third gate signal connection line is electrically connected to the third type shift register and the third gate line, respectively, which is not defined in the present disclosure.

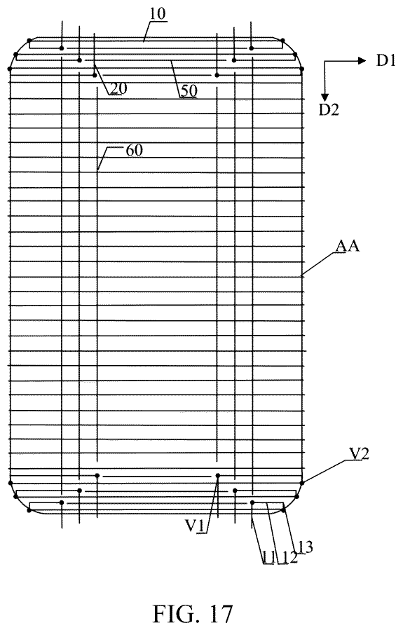

In an exemplary embodiment, FIG. 17 is a first schematic diagram of signal lines in a display region. As shown in FIGS. 8 to 15 and 17, any one of the first gate signal connection line to the M-th gate signal connection line may include a first connection line 11, a second connection line 12, and a third connection line 13. The first connection line 11 and the third connection line 13 extend in the second direction D2, and the second connection line 12 extends in the first direction D1.

In an exemplary embodiment, as shown in FIGS. 8 to 15 and 17, for the m-th gate signal connection line, the first connection line 11 is electrically connected to the m-th type shift register and the second connection line 12 connected to the m-th gate signal connection line, respectively, and the third connection line 13 is electrically connected to the second connection line 12 and the m-th gate line connected to the m-th gate signal connection line, respectively.

In an exemplary embodiment, the first connection line 11 may be provided in a different layer from any gate line in the gate line group 10. Since an orthographic projection of the first connection line on a base substrate is overlapped with an orthographic projection of a gate line in the gate line group on the base substrate, the first connection line 11 may be provided in a different layer from any gate line in the gate line group 10 to ensure normal transmission of signals of the first connection line and any gate line in the gate line group.

In an exemplary embodiment, the second connection line 12 and the third connection line 13 are provided in a same layer, and may be provided in a different layer from any gate line in any gate line group 10. By providing the second connection line 12 and the third connection line 13 in a same layer, a quantity of film layers occupied by the gate signal connection line may be reduced. In addition, the two are integrally formed, which may ensure stability of the connection, simplify the process, and ensure the lightness and thinness of the display substrate. In an exemplary embodiment, the first connection line 11 may be provided in a different layer from the second connection line 12.

In an exemplary embodiment, as shown in FIG. 17, for an m-th gate signal connection line, the first connection line 11 is electrically connected to the second connection line 12 through a first via V1, and the third connection line 13 is electrically connected to an m-th gate line connected by the m-th gate signal connection line through a second via V2. The first via V1 is located in the display region AA, the second via V2 is located outside the display region AA, and is spaced from a boundary of the display region by a distance less than a distance between a boundary of the gate driving circuit close to the display region and the display region. That is, the second via V2 is located at an edge of the display region AA, so that the gate signal connection line may be transferred to the edge of the display region and electrically connected to the gate line in the gate line group, thereby reducing a quantity of vias in the display region.

In an exemplary embodiment, as shown in FIGS. 8 to 15 and 17, the display region AA is further provided with a plurality of first traces 50. The plurality of first traces 50 extend in the first direction D1 and are arranged in the first direction D1 with second connection lines 12, and the first traces 20 and the second connection lines 12 are provided at intervals.

In an exemplary embodiment, the first traces 50 may be provided in a same layer as the second connection lines 12.

Provision of the first traces 50 in the present disclosure may ensure etching uniformity of the display substrate, and further improve display effects of the display substrate.

In an exemplary embodiment, as shown in FIGS. 8 to 15 and 17, the display region AA is further provided with a plurality of second traces 60. The plurality of second traces 60 extend in the second direction D2 and are arranged in the second direction D2 with first connection lines 11, and the second traces 60 and the first connection lines 11 are provided at intervals.

In an exemplary embodiment, the second traces 60 may be provided in a same layer as the first connection lines 11.

Provision of the second traces 60 in the present disclosure may ensure etching uniformity of the display substrate, and further improve display effects of the display substrate.

In an exemplary embodiment, FIG. 17 is a second schematic diagram of signal lines in a display region. As shown in FIG. 17, any one of the first gate signal connection lines to the M-th gate signal connection lines extends in the second direction D2.

In an exemplary embodiment, any one of the first gate signal connection line to the M-th gate signal connection line is provided in a different layer from any one of the gate lines in the gate line group.

In an exemplary embodiment, any one of the first gate signal connection line to the M-th gate signal connection line is electrically connected to the gate line in the gate line group through a via located in the display region. For example, when M=3, the first gate signal connection line is electrically connected to the first gate line in the gate line group through a via located in the display region, the second gate signal connection line is electrically connected to the second gate line in the gate line group through a via located in the display region, and the third gate signal connection line is electrically connected to the third gate line in the gate line group through a via located in the display region.

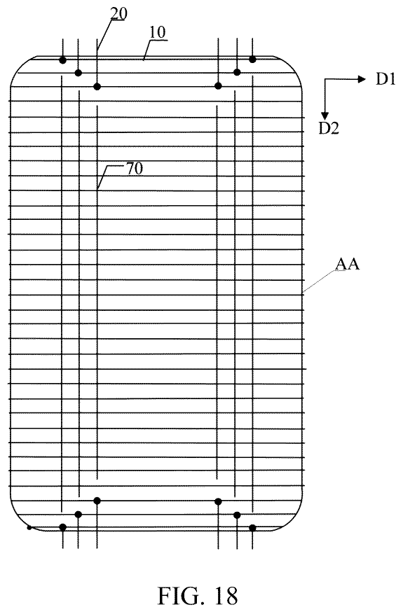

In an exemplary embodiment, as shown in FIG. 18, the display region AA is further provided with a plurality of third traces 70. The plurality of third traces 70 extend in the second direction D2, are arranged in the second direction with any one of the first gate signal connection line to the M-th gate signal connection line, and are provided at intervals therewith.

In an exemplary embodiment, the third traces 70 may be provided in a same layer as any one of the first gate signal connection line to the M-th gate signal connection line.

Provision of the third traces 70 in the present disclosure may ensure etching uniformity of the display substrate, and further improve display effects of the display substrate.

In an exemplary embodiment, the gate line group 10 and the gate connection line group 20 in FIGS. 5 to 18 only represent traces of any signal line in the gate line group 10 and the gate connection line group 20, and dots in FIGS. 5 to 18 only represent bends, and do not represent intersection and electrical connection.

In an exemplary embodiment, as shown in FIGS. 8 to 15, the non-display region is further provided with a first gate signal control line group to an M-th gate signal control line group, an m-th gate signal control line group is electrically connected to an m-th driving circuit, and the m-th gate signal control line group at least includes at least one clock signal line, an initial signal line, and at least one power supply line. As shown in FIGS. 8, 9, and 12 to 14, when M =3, the non-display region is further provided with a first gate signal control line group L1, a second gate signal control line group L2, and a third gate signal control line group L3. As shown in FIGS. 10, 11, and 15, when M=2, the non-display region is further provided with a first gate signal control line group L1 and a second gate signal control line group L2.

In an exemplary embodiment, as shown in FIGS. 8 to 15, at least some signal lines in the first gate signal control line group to the M-th signal control signal line group extend to the first straight-line frame region LR1, and at least some signal lines in the first gate signal control line to the M-th signal control signal lines extend to the binding region B2 through the second straight-line frame region LR2.

In an exemplary embodiment, at least some signal lines in the first gate signal control line group to the M-th signal control signal line group are located in the rounded corner frame region. FIGS. 8 and 9 are illustrated with an example in which the first gate signal control line group L1, the second gate signal control line group L2, and the third gate signal control line group L3 all extend to the first straight-line frame region LR1. FIGS. 10 and 11 are illustrated with an example in which the first gate signal control line group LI and the second gate signal control line group L2 both extend to the first straight-line frame region LR1. FIGS. 12 and 13 are illustrated with an example in which the second gate signal control line group L2 and the third gate signal control line group L3 both extend to the first straight-line frame region LR1. FIG. 14 is illustrated with an example in which the third gate signal control line group L3 extends to the first straight-line frame region LR1. FIG. 15 is illustrated with an example in which the second gate signal control line group L2 extends to the first straight-line frame region LR1.

An embodiment of the present disclosure further provides a display apparatus including a display substrate.

The display substrate is the display substrate according to any one of the aforementioned embodiments, implementation principles and implementation effects of which will not be repeated here.

In an exemplary embodiment, the display apparatus may be any product or component with a display function, such as a mobile phone, a tablet computer, a television, a display, a notebook computer, a digital photo frame, and a navigator, which is not defined in the present disclosure.

The drawings of the embodiments of the present disclosure only involve structures involved in the embodiments of the present disclosure, and other structures may refer to a general design.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although embodiments of the present disclosure are disclosed above, contents described are only embodiments used for ease of understanding of the present disclosure, but not intended to limit the present disclosure. Any of those skilled in the art of the present disclosure can make any modifications and variations in the implementation and details without departing from the spirit and scope of the present disclosure. However, the protection scope of the present disclosure should be subject to the scope defined by the appended claims.

1. A display substrate, comprising a display region and a non-display region, wherein the display region is provided with pixel driving circuits arranged in an array, a plurality of gate line groups and a plurality of gate connection line groups, the non-display region is provided with a gate driving circuit, a pixel driving circuit comprises a plurality of transistors, a gate line group is electrically connected to a gate electrode of at least one transistor and the gate driving circuit, respectively, the gate line group comprises at least one gate line, and any gate line in the gate line group extends at least partially in a first direction;
a boundary of the display region comprises a plurality of arc-shaped boundaries and a plurality of straight-line boundaries, any straight-line boundary is respectively connected to two arc-shaped boundaries, the non-display region comprises a frame region and a binding region which are sequentially provided in a direction away from the display region, the binding region is located on a side of the frame region, the frame region located outside a straight-line boundary is referred to as a straight-line frame region, the straight-line frame region comprises a first straight-line frame region and a second straight-line frame region arranged in a second direction, the first straight-line frame region is located on a side of the display region away from the binding region, the second straight-line frame region is located on a side of the display region close to the binding region, and the first direction intersects the second direction; and
a portion of the gate driving circuit is located in at least one of the first straight-line frame region and the second straight-line frame region, a gate connection line group is electrically connected to a local frame circuit and a gate line group connected to the local frame circuit, respectively, and the local frame circuit comprises a gate driving circuit located in at least one of the first straight-line frame region and the second straight-line frame region.

2. The display substrate according to claim 1, wherein the gate driving circuit comprises a first driving circuit to an M-th driving circuit, an m-th driving circuit comprises a plurality of cascaded m-th type shift registers, the gate driving circuit is divided into a plurality of shift register units corresponding one-to-one to the plurality of gate line groups, and the shift register units are electrically connected to the corresponding gate line groups, where 1≤m≤M; and
any shift register unit comprises a first type shift register to an M-th type shift register, and the gate line group comprises a first gate line to an M-th gate line.

3. The display substrate according to claim 2, wherein the first straight-line frame region and the second straight-line frame region are each divided into a first area and a second area which are respectively located on two sides of a first midline, and the first midline is a midline of the display region extending in the second direction;
the frame region further comprises a third straight-line frame region and a fourth straight-line frame region arranged in the first direction, and the third straight-line frame region and the fourth straight-line frame region are symmetrically provided relative to the first midline;
the gate driving circuit comprises a first gate driving group comprising an (N1+1)-th shift register unit to an N2-th shift register unit, and the first gate driving group is located in at least one of the third straight-line frame region and the fourth straight-line frame region, where N1<N, N2<N, and N2>N1, N being a quantity of shift register units included in the gate driving circuit; and
all shift register units in the first gate driving group are arranged in the second direction, and a first type shift register to an M-th type shift register located in any shift register unit in the first gate driving group are arranged in the first direction.

4. The display substrate according to claim 3, wherein the gate driving circuit further comprises a second gate driving group comprising a first shift register unit to an N1-th shift register unit, and a third gate driving group comprising an (N2+1)-th shift register unit to an N-th shift register unit; and
the second gate driving group is located in the first area of the first straight-line frame region, and the third gate driving group is located in the first area of the second straight-line frame region;
alternatively, the second gate driving group is located in the second area of the first straight-line frame region, and the third gate driving group is located in the second area of the second straight-line frame region;
alternatively, the second gate driving group is located in the first area and the second area of the first straight-line frame region, and the third gate driving group is located in the first area and the second area of the second straight-line frame region.

5. The display substrate according to claim 4, wherein the second gate driving group is located in the first area and the second area of the first straight-line frame region, and the second gate driving group located in the first area of the first straight-line frame region and the second gate driving group located in the second area of the first straight-line frame region are symmetrically provided with respect to the first midline; and
the third gate driving group is located in the first area and the second area of the second straight-line frame region, and the third gate driving group located in the first area of the second straight-line frame region and the third gate driving group located in the second area of the second straight-line frame region are symmetrically provided relative to the first midline.

6. The display substrate according to claim 4, wherein all shift register units located in the second gate driving group are arranged in the first direction, all shift register units located in the third gate driving group are arranged in the first direction, and a first type shift register to an M-th type shift register located in any one of the shift register units located in the second gate driving group and the third gate driving group are arranged in the second direction.

7. The display substrate according to claim 4, wherein all m-th type shift registers in the second gate driving group and the third gate driving group are referred to as an m-th type shift register group; and
in the first straight-line frame region and the second straight-line frame region, all shift registers located in a shift register group of a same type are arranged in the first direction, and a first type shift register group to an M-th type shift register group are arranged in the first direction.

8. The display substrate according to claim 3, wherein a rounded corner frame region comprises a first rounded corner frame region to a fourth rounded corner frame region, the first rounded corner frame region is located between the first straight-line frame region and the third straight-line frame region, the second rounded corner frame region is located between the first straight-line frame region and the fourth straight-line frame region, the third rounded corner frame region is located between the second straight-line frame region and the third straight-line frame region, and the fourth rounded corner frame region is located between the second straight-line frame region and the fourth straight-line frame region;
the gate driving circuit further comprises a second gate driving group comprising a first shift register unit to an N1-th shift register unit, and a third gate driving group comprising an (N2+1)-th shift register unit to an N-th shift register unit; and
the second gate driving group is located in the first area of the first straight-line frame region and the first rounded corner frame region, and the third gate driving group is located in the first area of the second straight-line frame region and the third rounded corner frame region;
alternatively, the second gate driving group is located in the second area of the first straight-line frame region and the second rounded corner frame region, and the third gate driving group is located in the second area of the second straight-line frame region and the fourth rounded corner frame region;
alternatively, the second gate driving group is located in the first area and the second area of the first straight-line frame region, the first rounded corner frame region and the second rounded corner frame region, and the third gate driving group is located in the first area and the second area of the second straight-line frame region, the third rounded corner frame region and the fourth rounded corner frame region.

9. The display substrate according to claim 8, wherein all m-th type shift registers in the second gate driving group and the third gate driving group are referred to as an m-th type shift register group; and
an i-th type shift register group in the second gate driving group is located in the first area of the first straight-line frame region, a j-th type shift register group in the second gate driving group is located in the first rounded corner frame region, an i-th type shift register group in the third gate driving group is located in the first area of the second straight-line frame region, and a j-th type shift register group in the third gate driving group is located in the third rounded corner frame region, where i is at least one number from 1 to M, and j is a remaining number from 1 to M except i;
alternatively, an i-th type shift register group in the second gate driving group is located in the second area of the first straight-line frame region, a j-th type shift register group in the second gate driving group is located in the second rounded corner frame region, an i-th type shift register group in the third gate driving group is located in the second area of the second straight-line frame region, and a j-th type shift register group in the third gate driving group is located in the fourth rounded corner frame region;
alternatively, an i-th type shift register group in the second gate driving group is located in the first area and the second area of the first straight-line frame region, a j-th type shift register group in the second gate driving group is located in the first rounded corner frame region and the second rounded corner frame region, an i-th type shift register group in the third gate driving group is located in the first area and the second area of the second straight-line frame region, and a j-th type shift register group in the third gate driving group is located in the third rounded corner frame region and the fourth rounded corner frame region.

10. The display substrate according to claim 9, wherein all shift registers in any type of shift register group located in any one of the first straight-line frame region and the second straight-line frame region are arranged in the first direction; and
a quantity of types of shift register groups located in any one of the first straight-line frame region and the second straight-line frame region is at least two, and at least two types of shift register groups located in any one of the first straight-line frame region and the second straight-line frame region are arranged in the second direction.

11. The display substrate according to claim 9, wherein all shift registers in any type of shift register group located in any one of the first straight-line frame region and the second straight-line frame region are arranged in the first direction; and
a quantity of types of shift register groups located in any one of the first straight-line frame region and the second straight-line frame region is at least two, and at least two types of shift register groups located in any one of the first straight-line frame region and the second straight-line frame region are arranged in the first direction.

12. The display substrate according to claim 9, wherein all shift registers in any type of shift register group located in at least one of the first rounded corner frame region, the second rounded corner frame region, the third rounded corner frame region, and the fourth rounded corner frame region are arranged along an arc-shaped boundary; and
a quantity of types of shift register groups located in the at least one of the first rounded corner frame region, the second rounded corner frame region, the third rounded corner frame region, and the fourth rounded corner frame region is at least two, and at least two types of shift register groups located in the at least one of the first rounded corner frame region, the second rounded corner frame region, the third rounded corner frame region, and the fourth rounded corner frame region are sequentially arranged in a direction away from the display region.

13. The display substrate according to claim 2, wherein a gate connection line group comprises a first gate signal connection line to an M-th gate signal connection line, and an m-th gate signal connection line is electrically connected to an m-th type shift register and an m-th gate line, respectively;
any one of the first gate signal connection line to the M-th gate signal connection line comprises a first connection line, a second connection line and a third connection line, the first connection line and the third connection line extend in the second direction, and the second connection line extends in the first direction; and
for the m-th gate signal connection line, the first connection line is electrically connected to the m-th type shift register connected to the m-th gate signal connection line and the second connection line, respectively, and the third connection line is electrically connected to the second connection line and the m-th gate line connected to the m-th gate signal connection line.

14. The display substrate according to claim 2, wherein a gate connection line group comprises a first gate signal connection line to an M-th gate signal connection line, and an m-th gate signal connection line is electrically connected to an m-th type shift register and an m-th gate line, respectively; and
the m-th gate signal connection line extends in the second direction.

15. The display substrate according to claim 12, wherein the first connection line is provided in a different layer from any gate line in the gate line group, and the second connection line and the third connection line are provided in a same layer and are provided in a different layer from any gate line in the gate line group; and
the first connection line is provided in a different layer from the second connection line.

16. The display substrate according to claim 15, wherein for an m-th gate signal connection line, the first connection line is electrically connected to the second connection line through a first via, the third connection line is electrically connected to an m-th gate line connected to the m-th gate signal connection line through a second via, the first via is located in the display region, and the second via is located outside the display region, and is spaced from a boundary of the display region by a distance less than a distance between a boundary of the gate driving circuit close to the display region and the display region.

17. The display substrate according to claim 13, wherein the display region is further provided with a plurality of first traces and a plurality of second traces;
the plurality of first traces extend in the first direction and are arranged in the first direction with second connection lines, and the first traces and the second connection lines are provided at intervals;
the plurality of second traces extend in the second direction and are arranged in the second direction with first connection lines, and the second traces and the first connection lines are provided at intervals; and
the first traces are provided on a same layer as the second connection lines, and the second traces are provided on a same layer as the first connection lines.

18. A display apparatus, comprising the display substrate according to claim 1.
